(19) United States
(12) Patent Application Publication
(10) Pub. No.: US 2025/0105189 A1
(43) Pub. Date: Mar. 27, 2025

(54) ELECTRONIC CHIP WITH CONNECTION PILLARS

(71) Applicant: STMicroelectronics International N.V., Geneva (CH)

(72) Inventor: Mohamed BOUFNICHEL, Monnaie (FR)

(73) Assignee: STMicroelectronics International N.V., Geneva (CH)

(21) Appl. No.: 18/891,787

(22) Filed: Sep. 20, 2024

(30) Foreign Application Priority Data
Sep. 25, 2023 (FR) 2310130

(51) Int. Cl. H01L 23/00; H01L 23/48; H01L 25/065

(52) U.S. Cl. CPC H01L 24/13; H01L 23/481; H01L 24/11; H01L 24/16; H01L 25/0657; H01L 2224/11462; H01L 2224/13022; H01L 2224/13024; H01L 2224/13027; H01L 2224/13139; H01L 2224/13144; H01L 2224/13147; H01L 2224/13155; H01L 2224/13582; H01L 2224/16145; H01L 2225/06513; H01L 2225/06541; H01L 2924/384

(57) ABSTRACT

The present description relates to an electronic circuit comprising a semiconductor substrate having opposed first and second faces and electrically conductive pillars, intended to be connected to an element external to the electronic circuit, extending through the semiconductor substrate from the second face to the first face and projecting from the first face.

### BACKGROUND

### Technical Field

The present description relates to the field of electrical connection between an electronic chip and a housing or between two electronic chips, and more particularly to connection pillars of the electronic chip.

### Description of the Related Art

To connect an electronic chip to an external element, connection pillars or pads can be provided on one face of the electronic chip and connected to conductive tracks on the electronic chip. In this way, the connection pillars can be brought into contact with conductive areas or tracks located on an external element, such as a housing or another electronic chip.

Using connection pillars can have some drawbacks, in particular the fragility of the connection pillars when they are small or when they have a high aspect ratio, the aspect ratio being the ratio between the height and the diameter of the connection pad, the high duration and cost of method for manufacturing the connection pad when the aspect ratio is high, and the risk of tearing the connection pillars away from the face of the electronic chip on which they are formed.

### BRIEF SUMMARY

One embodiment address all or some of the drawbacks of the known electronic chips comprising connection pillars.

One embodiment provides an electronic circuit comprising a semiconductor substrate (12) having opposed first and second faces and electrically conductive pillars, intended to be connected to an element external to the electronic circuit, extending through the semiconductor substrate from the second face to the first face and projecting from the first face.

According to an embodiment, the electronic circuit comprises, for each electrically conductive pillar, an electrically insulating layer located in the semiconductor substrate and completely surrounding the electrically conductive pillar in the semiconductor substrate.

According to an embodiment, the electronic circuit comprises an active area extending into the semiconductor substrate from the second face and including at least one electronic component, each electrically conductive pillar further comprising a connection track extending over the second face and electrically connected to the active area.

According to an embodiment, the electronic circuit further comprises at least one electrically insulating wall extending through the semiconductor substrate from the second face to the first face, and delimiting a semiconductor portion of the semiconductor substrate containing the active area.

According to an embodiment, the electrically insulating wall is separated from the electrically insulating layers surrounding the electrically conductive pillars by material of the semiconductor substrate.

According to an embodiment, the electrically insulating layers surrounding the electrically conductive pillars are part of the electrically insulating wall.

According to an embodiment, each electrically conductive pillar projects from the first face to a height greater than 25 μm.

One embodiment also provides a method of manufacturing an electronic circuit as previously defined, comprising, for each electrically conductive pillar, forming in the semiconductor substrate a first opening extending into the semiconductor substrate from the second face over a part of the thickness of the semiconductor substrate, and filling the first opening with an electrically conductive material.

According to an embodiment, the method comprises a step of thinning the semiconductor substrate on the side of the first face so that each electrically conductive pillar projects from the first face.

According to an embodiment, the method comprises, prior to filling the first openings with the electrically conductive material, a step of forming an electrically insulating layer on the walls of each first opening.

According to an embodiment, the method comprises forming at least one second opening extending into the semiconductor substrate from the second face over part of the thickness of the semiconductor substrate, the second opening being shallower than the first openings, and completely filling the second opening with electrically insulating material.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 is a schematic, partial cross-sectional view of an example electronic chip;

FIG. 2 is a schematic, partial cross-sectional view of an electronic chip;

FIG. 3, FIG. 4, FIG. 5, FIG. 6, FIG. 7, FIG. 8, FIG. 9, FIG. 10, FIG. 11, FIG. 12, and FIG. 13 are each a schematic, partial cross-sectional view of a structure obtained at one step of an embodiment of the manufacturing method for the electronic chip illustrated in FIG. 2;

FIG. 14 is a schematic, partial cross-sectional view illustrating the deposition of a conductive material on a connection pillar of the electronic chip shown in FIG. 1;

FIG. 15 is a schematic, partial cross-section illustrating the deposition of conductive material of a connection pillar of the electronic chip shown in FIG. 2;

FIG. 16, FIG. 17, FIG. 18, and FIG. 19 are schematic, partial top-section views of embodiments of the electronic chip of FIG. 2 at one step of the manufacturing method; and

FIG. 20 is a schematic, partial cross-sectional view of an embodiment of an electronic circuit.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%. Further, the terms “insulator” and “conductor” are taken here to mean “electrically insulating” and “electrically conductive” respectively.

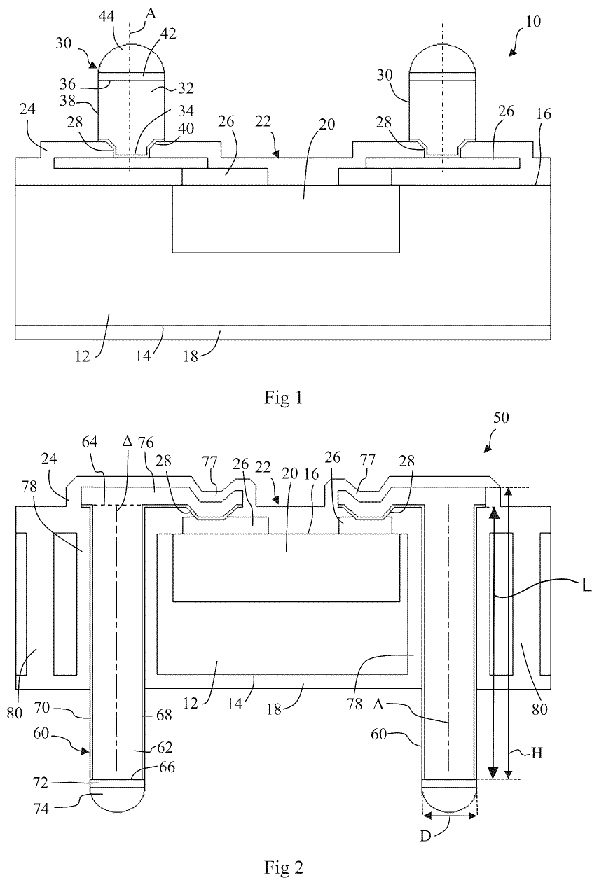

FIG. 1 is a schematic, partial cross-sectional view of an example electronic chip 10.

The electronic chip 10 comprises:
a semiconductor substrate 12 comprising a bottom face 14 and a top face 16;
an insulating layer 18 covering the bottom face 14;
an active area 20 in the substrate 12 flush with the top face 16, one or more electronic components, not shown, being formed in and/or on the active area 20;
an interconnection structure 22 covering the top face 16, comprising a stack of insulating layers 24 and conductive tracks 26 in and/or between the insulating layers 24, some of the conductive tracks 26 being in contact with the active area 20;
openings 28 in the stack of insulating layers 24, each exposing a part of one of the conductive tracks 26; and
connection pillars or pads 30, two connection pillars being shown by way of example in FIG. 1, each pillar being connected to one of the conductive tracks 26.

Each connection pillar 30 comprises a trunk 32 extending along an axis A substantially orthogonal to the top face 16. The trunk 32 comprises a base 34 on the side closest to the substrate 12, an end face 36 opposite the base 34 on the side furthest from the substrate 12, and a side wall 38 coupling the base 34 with the end face 36. The connection pillar 30 further comprises an interface layer 40 interposed between the base 34 and the interconnection structure 22. The pillar 30 further comprises a finishing layer 42 covering the end face 36 and a block 44 of a bonding material covering the finishing layer 42.

The use of connection pillars 30 as illustrated in FIG. 1 can have some drawbacks. Connection pillars 30 can be brittle when they are small in size, or when they have a high aspect ratio, also known as form factor. Further, each connection pillar 30 is mechanically linked to the interconnection structure 22 only by the interface layer 34. The method for manufacturing the connection pillar 30 may comprise etching steps that may result in partial etching of the interface layer 34 from its periphery. This weakens the bond between the trunk 32 and the interconnection structure 22. As a result, there is an increased risk of tearing the connection pillar 30 away from the connection structure 22. Furthermore, when the trunk 32 of the connection pillar 30 is made of copper, the trunk 32 is generally manufactured by electroplating by depositing copper from the interface layer 34. A drawback of this is the high duration and cost of the method for manufacturing the connection pad 30 when the aspect ratio of the connection pad 30 is high.

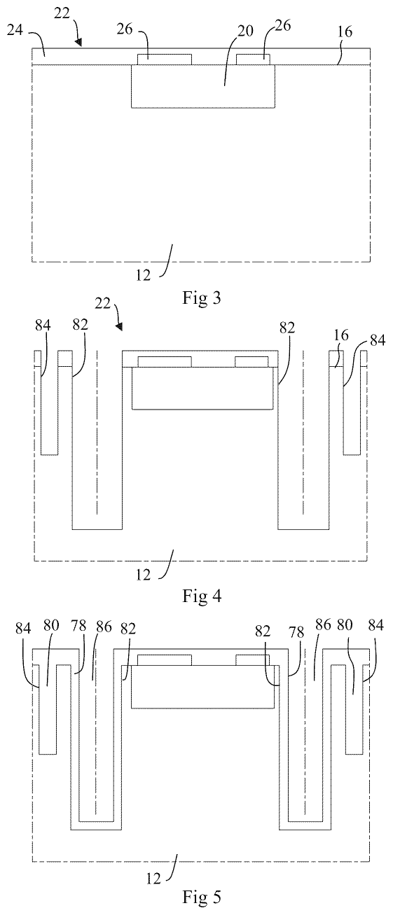

FIG. 2 is a schematic, partial cross-sectional view of an example electronic chip 50. The electronic chip 50 comprises all the elements of the electronic chip 10 shown in FIG. 1, except that the connection pillars 30 are replaced by connection pillars or pads 60.

According to one embodiment, each connection pillar 60 comprises:
a trunk 62 extending along an axis A substantially orthogonal to the top face 16 and passing through the substrate 12 from the top face 16 to the bottom face 14 and projecting out of the substrate 12 from the bottom face 14, the trunk 62 having a base 64 on the side closest to the top face 16 of the substrate 12, an end face 66 opposite the base 64 on the side closest to the bottom face 14 of the substrate 12, and a side wall 68 coupling the base 64 with the end face 66;
an interface layer 70 covering the side wall 68 of the trunk 62 and in direct physical contact with the side wall 68;
a finishing layer 72 covering the end face 66 and in direct physical contact with the end face 66;
a block 74 of bonding material covering the finishing layer 72;
a connection track 76 on the interconnection structure 22 and connecting the base 64 of the trunk 62 to one of the conductive tracks 26 in one of the openings 28, the interface layer 70 also being present between the connection track 76 and the interconnection structure 22; and
an insulating layer 77 covering each connection track 76.

The electronic chip 50 further comprises, for each pillar 60, an insulating layer 78 located in the substrate 12 and surrounding the trunk 62 over the entire part of the trunk 62 extending into the substrate 12 and interposed between the trunk 62 and the substrate 12. The insulating layer 78 extends into the substrate 12 over the entire thickness of the substrate 12, from the bottom face 14 to the top face 16. The insulating layer 78 is in direct physical contact with the interface layer 70.

According to one embodiment, the electronic chip 50 further comprises a lateral electrical isolation wall 80 extending into the substrate 12 over the entire thickness of the substrate 12, from the bottom face 14 to the top face 16. The wall 80 electrically isolates a part of the substrate 12 containing the active area 20 from the rest of the substrate 12.

Each pillar 60 is anchored in the substrate 12 over the entire thickness of the substrate 12. The mechanical strength of the connection pillar 60 is therefore advantageously improved compared to the pillar 30. Further, the risk of tearing the connection pillar 60 away is reduced.

According to one embodiment, the substrate 12 is made of silicon (Si), silicon carbide (SiC), III-V compound, in particular gallium nitride (GaN), or II-VI compound. The substrate 12 can have a single or multi-layered structure, e.g., a structure of the silicon on insulator (SOI) type. As an example, the substrate 12 may comprise a GaN layer overlying a silicon support. According to one embodiment, the thickness of the substrate 12 ranges from 50 μm to 300 μm.

The trunk 62 may have a substantially cylindrical shape with a Δ axis having a circular, square, or rectangular base, etc. The average dimension D, which in this embodiment is a diameter, of the trunk 62 ranges from 10 μm to 150 μm the average diameter D corresponding to the diameter of a trunk with a circular base whose surface is the same as that of the trunk 62. As shown in this embodiment in FIG. 2, the average diameter D remains the same from a first end (i.e., the base 64) of the trunk 62 that projects, protrudes, or extends outward from the first face 14 of the semiconductor substrate 12 and a second end (i.e., the end face 66) opposite to the first end that projects, protrudes, or extends outward from the second face 16 of the semiconductor substrate 12. In other words, the average diameter D remains the same along a length L of the trunk 62 extending from the first end (i.e., the base 64) to the second end (i.e., the end face 66) of the trunk 62. According to one embodiment, the end face 66 is substantially perpendicular to the axis A. The trunk 62 and connection track 76 are made of metal, for example copper, nickel, silver, gold, or an alloy of these metals. The overall height H of the trunk 62 from the end face 66 to the top face of the connection track 76 ranges from 75 μm to 400 μm. The height of the trunk 62 projecting from the insulating layer 18 ranges from 25 μm to 100 μm. The aspect ratio of trunk 62, which corresponds to the ratio between the overall height H of the trunk 62 and the average diameter D of the trunk 62, ranges from 0.5 to 40.

The metal tracks 26 are, for example, made of materials selected from copper, a copper alloy, titanium, a titanium alloy, titanium nitride, platinum, and a platinum alloy. According to one embodiment, the thickness of each metal track 26 ranges from 0.5 μm to 1.5 μm.

Each insulating layer 18, 24, 77, and 78, and each insulating wall 80 can be made of a dielectric material, e.g., silicon oxide (SiO₂), silicon nitride (e.g., Si₃N₄), silicon oxynitride (e.g., Si₂ON₂), or hafnium oxide (HfO₂). According to one embodiment, the thickness of the insulating layer 18 ranges from 0.1 μm to 0.5 μm. According to one embodiment, the thickness of each insulating layer 24 ranges from 0.5 μm to 1.5 μm. According to one embodiment, the thickness of the insulating layer 77 ranges from 0.5 μm to 1.5 μm. According to one embodiment, the thickness of the insulating layer 78 ranges from 0.2 μm to 1 μm. According to one embodiment, the thickness of the wall 80 ranges from 1 μm to 3 μm.

The thickness of the interface layer 70 ranges from 10 nm to 1 μm. The interface layer 70 acts as a primer for the formation of the trunk 62 and connection track 76 of the connection pillar 60. The interface layer 70 may comprise a titanium or chromium layer, acting as an adhesion layer, and a copper layer acting as a primer layer for the subsequent formation of the trunk 62 and connection track 76.

The thickness of the finishing layer 72 ranges from 10 nm to 5 μm, for example 3 μm. Finishing layer 72 is made of a conductive material that improves adhesion of block 74. Finishing layer 72 is made, for example, of metal, in particular gold or silver, and optionally comprises one or more bonding layers and/or one or more barrier layers, comprising, for example, platinum (Pt), palladium (Pd), nickel (Ni), titanium (Ti), chromium (Cr), and/or tantalum (Ta), between the trunk material 62 and the block material 74 which is deposited on the trunk 62. The finishing layer 72 further allows oxidation of the end face 66 of the trunk 62 to be prevented in the case where the assembly method is not carried out in a neutral or reducing atmosphere.

The material forming the block 74 depends in particular on the assembly method implemented to attach the electronic chip 50 to another component. In particular, the assembly method may include a welding step or a sintering step. The material forming the 74 block may include an active filler comprising particles of a metallic material, for example silver, copper, tin, or an alloy of these metals. The active filler may further comprise gold and other additives, such as polymers and/or ceramics, which do not participate in the attachment of the connection pillar, but facilitate the methods for implementing the block 74. The height of the block 74, measured from top layer 72, may be around 25 μm.

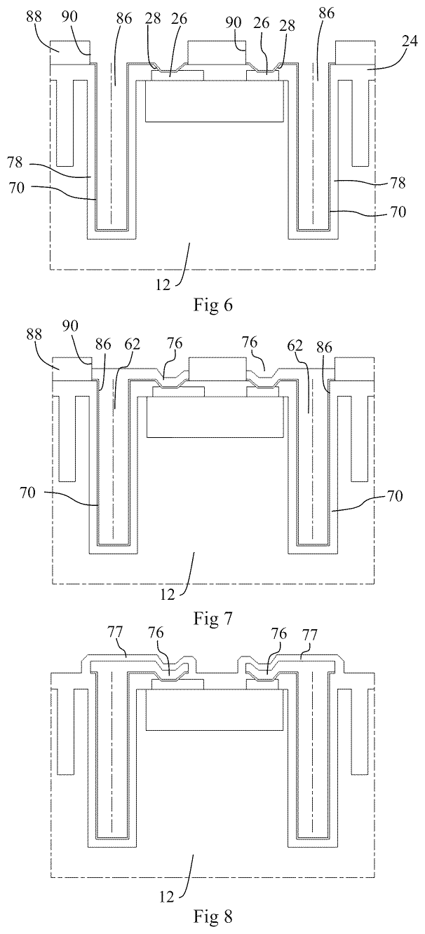

FIG. 3, FIG. 4, FIG. 5, FIG. 6, FIG. 7, FIG. 8, FIG. 9, FIG. 10, FIG. 11, FIG. 12, and FIG. 13 are each a schematic, partial cross-sectional view of a structure obtained at one step of an embodiment of a method for manufacturing the electronic chip 50 shown in FIG. 2.

FIG. 3 illustrates the structure obtained after the formation of the active area 20 and the formation of the interconnection structure 22 on the top face 16 of the substrate 12. One or more electronic components, not shown, are formed in and/or on the active area 20. According to one embodiment, at this stage of the procedure, the substrate 12 corresponds to a plate, and the active areas 20 of several electronic chips are formed in and/or on the substrate 12, the active areas 20 being able to be identical or different. In FIG. 3, a single active area 20 is illustrated and the interconnection structure 22 comprises two conductive tracks 26 connected to the active area 20, and one insulating layer 24 covering the conductive tracks 26 and the top face 16 of the substrate 12 around the conductive tracks 26. At this stage of the method, the thickness of the substrate 12 is greater than the desired final thickness of the substrate 12. The thickness of the substrate 12 at this stage of the method can range from 500 μm to 1.3 mm.

FIG. 4 illustrates the structure obtained after forming an opening 82 at the desired location of each connection pillar 60, and forming an opening 84 at the desired location of each wall 80. The openings 82 and 84 pass completely through the interconnection structure 22, and extend over part of the thickness of the substrate 12 from the top face 16. The openings 82 have a same depth, and the openings 84 have a same depth. The depth of openings 82 is greater than the depth of openings 84. According to one embodiment, the depth of openings 84 is substantially equal to the desired final thickness of the substrate 12. The depth of openings 84 can range from 50 μm to 300 μm. According to one embodiment, the openings 82 and 84 are performed by Deep Reactive Ion Etching (DRIE). Depending on the method used to form the openings 82 and 84, the openings 82 and 84 can be performed simultaneously or in separate steps. In particular, with deep reactive ion etching, the etching speed depends on the opening diameter, so that the openings 84 having a width less than the average diameter of the openings 82 can be performed simultaneously with the openings 82.

FIG. 5 illustrates the structure obtained after forming the insulating layer 78 in each opening 82, and forming the insulating wall 80 in each opening 84. At this stage of the method, the insulating layer 78 covers the sidewalls and bottom of the opening 82. This step may comprise depositing an insulating layer simultaneously on the walls of the opening 84 and on the walls of the opening 82, the thickness of the insulating layer being such that it completely fills the opening 84 but does not completely fill each opening 82 so that a cavity 86 is present in each opening 82 after formation of the insulating layer.

FIG. 6 illustrates the structure obtained after forming, for each connection pillar to be made, the opening 28 in the insulating layer 24 to expose one of the conductive tracks 26, depositing a mask 88 on the insulating layer 24 comprising, for each connection pillar to be made, an opening 90 exposing the cavity 86, the opening 28 and the part of the insulating layer 24 coupling the cavity 86 with the opening 28, and forming the interface layer 70 in each opening 90. At this stage of the method, the interface layer 70 covers all the walls of cavity 86, in particular the side walls and bottom of cavity 86, the walls of opening 28, and the exposed part of insulating layer 24 coupling the cavity 86 with the corresponding opening 28. The mask 88 may correspond to a film applied over the insulating layer 24.

FIG. 7 illustrates the structure obtained after, for each connection pillar to be formed, completely filling each cavity 86 with a conductive material, thus forming the trunk 62 of the connection pillar, and forming the connection portion 76 of each connection pillar. The conductive material making up the trunk 62 can be deposited by electroplating on the interface layer 70. In this case, depositing the conductive material is performed from the interface layer 70 in a direction substantially perpendicular to the interface layer 70. This advantageously enables the cavity 86 to be filled even if the form factor of the cavity 86, i.e., the ratio between the height of the cavity and the diameter of the cavity, is high, since the conductive material is deposited in particular from the side walls of the cavity 86.

FIG. 8 illustrates the structure obtained after removing the film 88, and forming, for each connection pillar, the insulating layer 77 covering the connection track 76.

FIG. 9 illustrates the structure obtained after etching the substrate 12 from the bottom face 14 of the substrate 12. At the end of the etching step, for each connection pillar, a part of the trunk 62, surrounded by the interface layer 70 and the insulating layer 78, projects out of the substrate 12 from the bottom face 14 over a height H′. The etching step may comprise selective chemical etching with respect to the material forming the insulating layer 78. According to one embodiment, etching the substrate 12 is stopped when the end of the wall 80 is flush with the bottom face 14. The height H′ is set by the etching step.

FIG. 10 illustrates the structure obtained after forming the insulating layer 18 on the bottom face 14 of the substrate 12. According to one embodiment, the insulating layer 18 is made of the same material as the insulating layer 78, and the thickness of the insulating layer 18 at this stage of the method, is substantially equal to the sum of the thickness of the insulating layer 78 and the desired final thickness of the insulating layer 18, e.g., equal to twice the thickness of the insulating layer 78.

FIG. 11 illustrates the structure obtained after completely etching the portion of the insulating layer 78 exposed on the side of the bottom face 14 of substrate 12. This step may further cause etching the insulating layer 18 through the thickness of the insulating layer 78. The insulating layer 18 with the desired final thickness is then obtained.

FIG. 12 illustrates the structure obtained after, for each connection pillar 60, etching the interface layer 70 covering the end face 66, forming the top layer 72, and forming the block 74 of bonding material.

FIG. 13 illustrates the structure obtained after a cutting step to separate the electronic chips 50. According to one embodiment, the cutting lines 91 are located between the walls 80 of adjacent electronic chips 50.

Each electronic chip 50 thus individualised can then be attached to an external element, such as a housing or another electronic chip. The wall 80 protects the active area 20 of the electronic chip 50 in particular against electrostatic discharges at the side walls of the electronic chip 50 during handling and attachment of the electronic chip 50 to the external element.

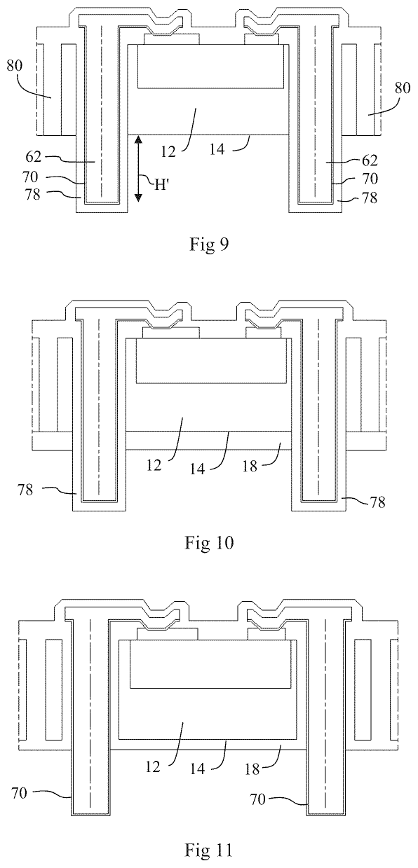

FIG. 14 is a schematic, partial cross-sectional view illustrating the formation of a connection pillar 30 of the electronic chip of FIG. 1. FIG. 14 shows the structure obtained after depositing a mask 92 on the interconnection structure 22 comprising, for each connection pillar to be performed, an opening 94 exposing the opening 28, forming the interface layer 40 on the part of the interconnection structure 22 exposed in the opening 94, and depositing the conductive material to form the trunk 32 of the connection pillar. The conductive material forming the trunk 32 can be deposited by electroplating on the interface layer 70. In this case, depositing the conductive material is performed from the interface layer 70 along a direction substantially perpendicular to the interface layer 70, as illustrated by the arrows F1 parallel to the axis A of the trunk 32. To form the trunk 32, one should thus deposit the conductive material substantially over a height H″ measured along the axis A. The precision of the height H″ of the trunk 62 that can be achieved depends essentially on the precision that can be achieved with the electroplating method.

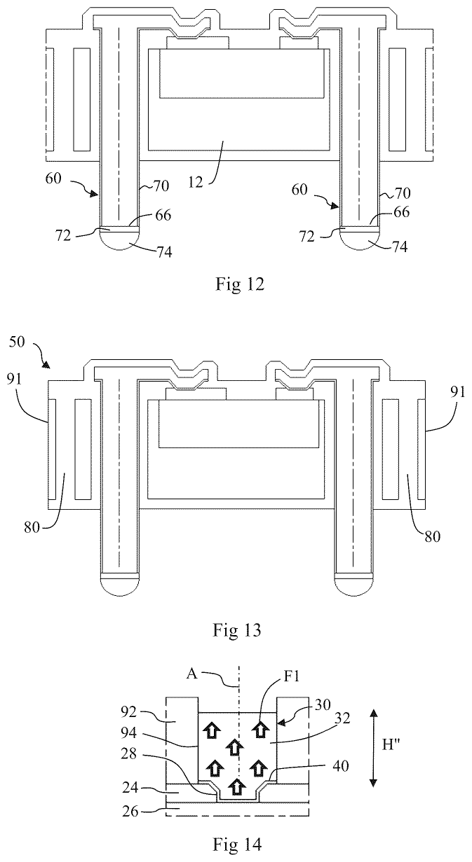

FIG. 15 is a schematic, partial cross-sectional view illustrating the formation of a connection pillar 60 of the electronic chip of FIG. 2 corresponding to the step described above in relation to FIG. 7. The conductive material making up the trunk 62 can be deposited by electroplating on the interface layer 70. In this case, depositing the conductive material is performed from the interface layer 70 along a direction substantially perpendicular to the interface layer 70, as illustrated by arrows F2. To form the trunk 62, the conductive material should thus be deposited substantially over a thickness equal to half the average diameter D of the trunk 62. The duration of the trunk-forming step 62 is therefore substantially independent of the total height of the trunk 62, and also of the height of the trunk 62 which, on the finished electronic chip, protrudes from the bottom face 14 of the substrate 12. Indeed, this height is defined by the step of thinning substrate 12 described above in relation to FIG. 9. As half of the average diameter D of the trunk 62 is less than the height H″ shown in FIG. 14, the duration of the step of forming the trunk 62 by electroplating can advantageously be reduced compared to the duration of forming the trunk 32.

The precision achievable on the height H of the trunk 62 mainly depends on the precision achievable by the etching method implemented to form the opening 82. Advantageously, the precision achievable on the height H of the trunk 62 is greater than the precision achievable on the height H″ of the trunk 32. Further, the precision achievable on the height of the part of the trunk 62 projecting from the bottom face 16 mainly depends on the precision achievable by the etching method implemented to form the opening 82, and the precision achievable by the method implemented to thin the substrate 12. Advantageously, the precision achievable on the height of the part of the trunk 62 projecting from the bottom face 16 is greater than the precision achievable on the height H″ of the trunk 32. The homogeneity of the heights of the projecting parts of the connection pillars 60 is improved.

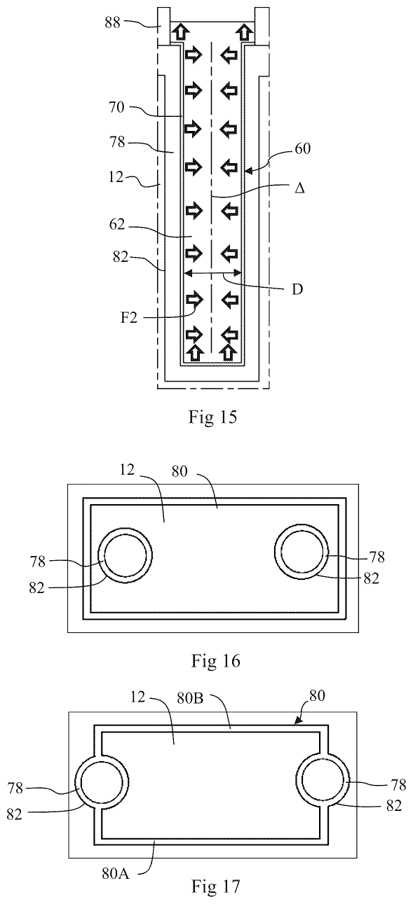

FIG. 16, FIG. 17, FIG. 18, and FIG. 19 are each schematic, partial top-section views of the structures obtained in the step described above in relation to FIG. 5 for different embodiments of the electronic chip of FIG. 2. In FIGS. 16 to 19, the cross-sectional plane lies between the bottom face 14 and the top face 16 of the substrate 12, and is parallel to the top face 16.

In FIGS. 16 and 17, the openings 82 have a circular straight section. In FIGS. 18 and 19, the openings 82 have a rectangular section with rounded corners.

In FIGS. 16 and 18, the wall 80 is separated from each insulating layer 78 by a portion of the substrate 12 and surrounds the two openings 82. In FIGS. 17 and 19, the wall 80 comprises two sub-walls 80A and 80B, each sub-wall 80A and 80B joining at its ends the insulating layer 78 intended to surround a connection pillar. The insulating layers 78 intended to surround the connection pillars are then part of the wall 80.

Advantageously, according to the embodiment previously described in relation to FIGS. 3 to 13, the wall 80 is formed simultaneously with the openings 82 and the insulating layers 78. Thus, no additional steps are required to form the wall 80.

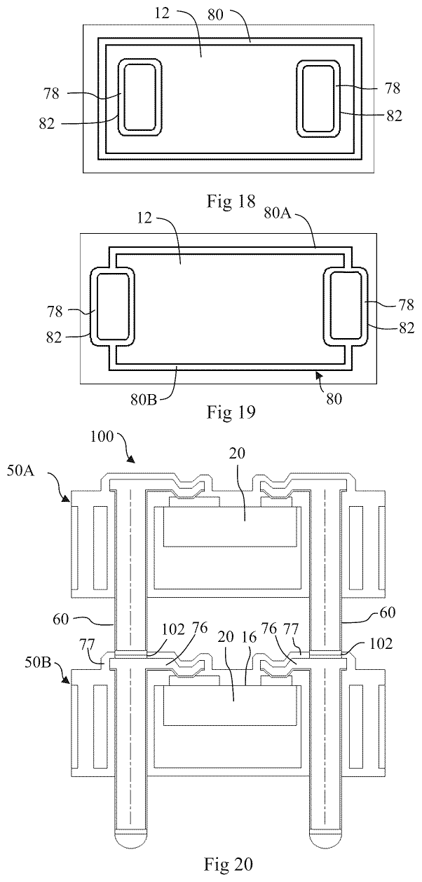

FIG. 20 is a schematic, partial cross-sectional view of an embodiment of an electronic circuit 100.

The electronic circuit 100 comprises a stack of two electronic chips 50A and 50B, each with the structure illustrated in FIG. 2. The active areas 20 of the electronic chips 50A and 50B may contain different electronic components and/or be differently arranged. The connection pads 60 on the electronic chip 50A are attached to the electronic chip 50B on the side of the top face 16 of the electronic chip 50B. In FIG. 20, the connection pads 60 of the electronic chip 50A are attached to the connection tracks 76 of the electronic chip 50B through the openings 102 provided in the insulating layer 77 covering the connection tracks 76 of the electronic chip 50B.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

An electronic circuit (50) of the present disclosure includes a semiconductor substrate (12) having opposed first and second faces (14, 16) and electrically conductive pillars (60), intended to be connected to an element external to the electronic circuit, extending through the semiconductor substrate (12) from the second face (16) to the first face (14) and projecting from the first face (14).

The electronic circuit includes, for each electrically conductive pillar (60), an electrically insulating layer (78) located in the semiconductor substrate (12) and completely surrounding the electrically conductive pillar in the semiconductor substrate (12).

The electronic circuit includes an active area (20) extending into the semiconductor substrate (12) from the second face (16) and including at least one electronic component, each electrically conductive pillar (60) further including a connection track (76) extending over the second face (16) and electrically connected to the active area (20).

The electronic circuit further includes at least one electrically insulating wall (80) extending through the semiconductor substrate (12) from the second face (16) to the first face (14), and delimiting a semiconductor portion of the semiconductor substrate (12) containing the active area (20).

The electrically insulating wall (80) is separated from the electrically insulating layers (78) surrounding the electrically conductive pillars (60) by material of the semiconductor substrate (12).

The electrically insulating layers (78) surrounding the electrically conductive pillars (60) is part of the electrically insulating wall (80).

Each electrically conductive pillar (60) projects from the first face (14) to a height greater than 25 μm.

A method of manufacturing an electronic circuit (60) of the present disclosure includes for each electrically conductive pillar (60), forming in the semiconductor substrate (12) a first opening (82) extending into the semiconductor substrate (12) from the second face (16) over a part of the thickness of the semiconductor substrate (12), and filling the first opening (82) with an electrically conductive material.

The method includes a step of thinning the semiconductor substrate (12) on the side of the first face (14) so that each electrically conductive pillar (60) projects from the first face (14).

The method includes prior to filling the first openings (82) with the electrically conductive material, a step of forming an electrically insulating layer (78) on the walls of each first opening (82).

The method includes forming at least one second opening (84) extending into the semiconductor substrate (12) from the second face (16) over part of the thickness of the semiconductor substrate (12), the second opening (84) being shallower than the first openings (82), and completely filling the second opening (84) with electrically insulating material.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a semiconductor substrate having opposed first and second faces; and
a plurality of electrically conductive pillars configured to be connected to an element external to the semiconductor substrate, the plurality of electronically conductive pillars extending through the semiconductor substrate from the second face to the first face, and each respective electrically conductive pillar of the plurality of electrically conductive pillars includes:
a trunk portion that extends entirely through the semiconductor substrate from the first and second faces, the trunk portion includes:
a first end that projects from the first face;
a second end opposite to the first end that projects from the second face; and
a dimension in a direction transverse to the first and second faces that remains the same from the first end to the second end.

2. The electronic circuit according to claim 1, comprising, for each electrically conductive pillar, an electrically insulating layer located in the semiconductor substrate and completely surrounding the electrically conductive pillar in the semiconductor substrate.

3. The electronic circuit according to claim 1, comprising an active area extending into the semiconductor substrate from the second face and including at least one electronic component, each electrically conductive pillar further comprising a connection track extending over the second face and electrically connected to the active area.

4. The electronic circuit according to claim 1, further comprising at least one electrically insulating wall extending through the semiconductor substrate from the second face to the first face, and delimiting a semiconductor portion of the semiconductor substrate containing the active area.

5. The electronic circuit according to claim 2, wherein the electrically insulating wall is separated from the electrically insulating layers surrounding the electrically conductive pillars by material of the semiconductor substrate.

6. The electronic circuit according to claim 2, wherein the electrically insulating layers surrounding the electrically conductive pillars are part of the electrically insulating wall.

7. The electronic circuit according to claim 1, wherein each electrically conductive pillar projects from the first face to a height greater than 25 μm.

8. A method, comprising:
forming a first opening extending into the semiconductor substrate from a second face over a first part of the thickness of the semiconductor substrate;
forming a second opening extending into a semiconductor substrate from the second face over a second part of the thickness of the semiconductor substrate, the second part being shallower than the first part; and
partially filling the first opening with an insulting material;
filling the second opening with the insulating material; and
filling a remaining portion of the first opening with one or more electrically conductive materials forming an electrically conductive pillar.

9. The method according to claim 8, further comprising thinning the semiconductor substrate at the first face so that the electrically conductive pillar projects from the first face of the semiconductor substrate.

10. The method according to claim 8, partially filling the first opening with the insulating material further includes forming the insulating material on one or more walls of the semiconductor substrate that delimit the first opening.

11. The method according to claim 8, further comprising forming a mask layer on the insulating material including an opening that expose a region of the insulating material within the first opening, and
wherein filling a remaining portion of the first opening with one or more electrically conductive material forming an electrically conductive pillar includes:
forming a electrically conductive interface layer on one or more walls of the insulating material partially filling the first opening; and
forming an electrically conductive plating material on the electrically conductive interface layer.

12. A device, comprising:
a semiconductor substrate having a first face, a second face opposite to the first face, and one or more sidewalls that are transverse to the first face and the second face and extend from the first face to the second face; and
a plurality of electrically conductive pillars configured to be connected to an element external to the semiconductor substrate, the plurality of electronically conductive pillars extending through the semiconductor substrate from the second face to the first face, and each respective electrically conductive pillar of the plurality of electrically conductive pillars includes:
a trunk portion that extends entirely through the semiconductor substrate from the first and second faces, the trunk portion includes:
a first end that projects from the first face;
a second end opposite to the first end that projects from the second face; and
an insulating material extends through the semiconductor substrate from the first face to the second face, the insulating material covers the first face and the second face, and the insulating material includes one or more sidewalls coplanar with the one or more sidewalls of the semiconductor substrate.

13. The device of claim 12, wherein first ends of the plurality of electrically conductive pillars are coupled to a plurality electrically conductive connection tracks that are coupled between the first ends of the plurality of electrically conductive connection tracks and a plurality of conductive tracks on the second face of the semiconductor substrate.

14. The device of claim 13, wherein the plurality of conductive tracks overlap an active area of the semiconductor substrate.

15. The device of claim 12, wherein the semiconductor substrate includes an active area spaced inward from the plurality of electrically conductive pillars.

16. The device of claim 12, wherein the insulting material includes a wall that surrounds the plurality of electrically conductive pillars and an active area of the semiconductor substrate.

17. The device of claim 12, wherein the insulating material includes a plurality of first portions and a wall portion, each respective first portion of the plurality of first portions surrounds a corresponding electrically conductive pillar of the plurality of pillars.

18. The device of claim 17, wherein the wall portion surrounds the plurality of first portions, the plurality of electrically conductive pillars, and an active area of the semiconductor substrate.

19. The device of claim 18, wherein the wall portion is separated from the plurality of first portions by a portion of the semiconductor substrate.

20. The device of claim 17, wherein the wall portion is part of the plurality of first portions.
